(19) United States
(12) Patent Application Publication
(10) Pub. No.: US 2022/0158075 A1
(43) Pub. Date: May 19, 2022

(54) FLEXIBLE AND LOW COST LEAD-FREE PIEZOELECTRIC COMPOSITES WITH HIGH D33 VALUES

(71) Applicant: SABIC Global Technologies B.V., Bergen op Zoom (NL)

(72) Inventors: Jibran KHALIQ, Delft (NL); Sybrand VAN DER ZWAAG, Delft (NL); Pim GROEN, Delft (NL); Jesus Alfonso Caraveo FRESCAS, Thuwal (SA); Soma GUHATHAKURTA, Bangalore (IN); Suresh VELATE, Bangalore (IN)

(73) Assignee: SABIC Global Technologies B.V., Bergen op Zoom (NL)

(21) Appl. No.: 17/594,017

(22) PCT Filed: Mar. 25, 2020
(86) PCT No.: PCT/IB2020/052803

§ 371 Date: Sep. 30, 2021

(30) Foreign Application Priority Data
Apr. 2, 2019 (IN) 201911013228

(51) Int. Cl. H01L 41/18; C08K 3/22; C08F 214/22; C08F 214/18; C08J 5/18; C08J 3/21; H01L 41/257; H01L 41/37

(52) U.S. Cl. CPC H01L 41/183; C08K 3/22; C08F 214/22; C08F 214/182; C08J 5/18; C08J 2327/16; H01L 41/257; H01L 41/37; C08K 2003/2237; C08K 2003/2203; C08J 3/212

(57) ABSTRACT

Lead-free piezoelectric composites and methods of making and uses thereof are described. The lead-free piezoelectric composites have high flexibility and high piezoelectric properties.

### CROSS REFERENCE TO RELATED APPLICATIONS

This application claims the benefit of priority of Indian Patent Application No. 201911013228, filed Apr. 2, 2019, which is hereby incorporated by reference in its entirety.

### BACKGROUND OF THE INVENTION

A. Field of the Invention

The invention generally concerns a lead-free piezoelectric composite having high flexibility and high piezoelectric properties.

B. Description of Related Art

For human-machine interactions or for wearable devices, a new class of materials are required, which are both mechanically flexible and able to operate at lower voltages. A smart watch is an example of such a device. Conventional smart watches can use eccentric rotating mass (ERM) to create vibrations. These watches can be connected to a smart phone via Bluetooth and a unique rhythm of vibrations can be assigned to each individual caller to allow identification of the caller without looking at the phone screen or the watch display. Wearable devices that include ERM suffer from being heavy. To overcome the weight issue, linear actuators (LA) have been incorporated in wearable devices. Linear actuators use a voice coil which is pressed against a mass attached to a spring. The spring vibrates at the resonance frequency when an AC field is applied to the coil thereby vibrating the mass. These linear actuators are relatively lighter than ERM. However they also suffer from being heavy due to their construction and mass attached to it. Further, LAs lack flexibility and have large volumes, which can make wearable devices thick.

To overcome the problems of ERMs and LAs, piezoelectric materials have been investigated. Piezoelectric materials can be ceramic, single crystalline in nature, or polymeric. Ceramics can have relatively high dielectric constants as compared to polymers and good electromechanical coupling coefficients. Ceramics suffer from high acoustic impedance, which results in poor acoustic matching with media such as water and human tissue—the media through which it is typically transmitting or receiving a signal. In addition, ceramics can exhibit high stiffness and brittleness and cannot be formed onto curved surfaces, which contributes to limited design flexibility in a given transducer. Further, the electromechanical resonances of piezoelectric ceramics give rise to a high degree of noise, which is an unwanted artifact in the context of transducer engineering. Lead is typically used in piezoceramics to obtain acceptable piezoelectric constants. However, lead is heavy and can be toxic. Lead-free piezoceramics have lower piezoelectric constants thereby making it difficult to achieve acceptable piezoelectric performance. For example, the d₃₃ of PZT is ˜270-400 pC/N, which is much higher than the d₃₃ of barium titanate, which is ˜190 pC/N. Single crystal piezoelectric material can include crystals of quartz tourmaline and potassium-sodium tartrate. Other single crystals can include lead metaniobate (PbNb₂O₆) or relaxor systems such as Pb(Sc_{1/2}Nb_{1/2})O₃—PbTiO₃, Pb(In_{1/2}Nb_{1/2})O₃—PbTiO₃ and Pb(Yb_{1/2}Nb_{1/2})O₃—PbTiO₃, (1-2×) BiScO₃—×PbTiO₃. As with ceramics, any one single piezoelectric material phase (ceramic or crystal or polymer) does not provide all of the desired features for an application, and the performance is thereby limited by the trade-off between high piezoelectric activity and low density with mechanical flexibility.

Piezoelectric polymer materials such as PVDF and PVDF-TrFE copolymer offer several advantages, which include mechanical flexibility, light weight, low temperature and ease of processing. Despite such advantages, these materials suffer due to their lower piezoelectric response (d₃₃˜13-28 pC/N) compared to the ceramics (d₃₃ of PZT ranges from 270-400 pC/N) and the requirement of higher driving voltage which poses additional safety and cost concerns.

Attempts have been made to address the aforementioned problems. For Example, U.S. Patent Application Publication No. 2015/0134061 to Friis et al. describes a spinal implant and a method of making the spinal implant that includes dispersing a piezoelectric ceramic in a polymer matrix. Unfortunately, the produced composites have low d₃₃(pC/N) values of less than 3. In another example, JP2016-219804 to Tetsuhiro et al. describes methods of making lead-free piezoelectric polymer materials that include the use of an affinity improver such as surfactants to aid in dispersing the particles in the polymeric matrix. Affinity improver can be difficult to remove from the desired polymer matrix and/or are costly.

Although various attempts to produce piezoelectric composites have been made, there is still a need to produce lead-free piezoelectric composites with a balance of desired piezoelectric performance with the mechanical flexibility.

### SUMMARY OF THE INVENTION

A discovery has been made that provides a solution to at least some of the aforementioned problems associated with flexible devices (e.g., wearable devices). The solution is premised in the discovery of a lead-free piezoelectric composite that can be structured such that it includes a polymeric matrix having a dielectric constant greater than 30 at 20° C. The matrix can be loaded with greater than 10 vol. % of a lead-free piezoelectric material based on the total volume of the composite. This lead-free material can dispersed throughout the polymeric matrix. This can result in the composite having an elastic modulus of less than 1 GPa and a piezoelectric coefficient d₃₃ of greater than 20 pC/N. Using a lead-free piezoelectric composite material of the present invention can provide the advantages of flexibility and higher blocking forces as compared to polymer-based actuators such as PVDF-based actuators. Replacing linear actuators with the piezocomposite composite of the present invention can also result in thinner wearable devices, thus reducing the overall manufacturing cost of the wearable device. Other advantages of the present invention can include incorporation of the lead-free piezoelectric composites into straps of wearable devices, which can have a “wrist band” like feeling that can wholly or partially cover human body parts (e.g., wrist, arm, leg, finger, hand, head, neck, foot, etc.).

Additional advantages of the lead-free piezoelectric composite materials of the present invention include high flexibility (elastic modulus of less than 1 GPa) and higher piezoelectric properties as compared to PVDF (d₃₃ of PVDF 15-30 pC/N, while d₃₃ for piezocomposite 40-52 pC/N). The composites of the present invention can have low poling voltages compared to PVDF (e.g., the poling voltage for PVDF is typical about 80 to 180 KV/mm, whereas the poling voltage of the composites of the present invention can be 8 to 12 KV/mm). The composites of the present invention can maintain mechanical flexibility even at higher lead-free piezoelectric filler loadings (e.g., at 10 vol. % or greater loadings). Further, the composites of the present invention can have low processing temperatures, which allows for the integration of various materials that are typically susceptible to breakdown under heat (e.g., polymers). The lower processing temperatures can also reduce the production costs of the piezocomposites of the present invention when compared to PVDF and PVDF-based materials.

In one aspect of the present invention, lead-free piezoelectric composites are described. A lead-free piezoelectric composite can include a polymeric matrix having a dielectric constant greater than 30 at 20° C. and can include greater than 10 vol. % of a lead-free piezoelectric material based on the total volume of the composite dispersed throughout the polymeric matrix. Such a lead-free piezoelectric composite can have an elastic modulus of less than 1 GPa, and a piezoelectric coefficient d₃₃ of greater than 20 pC/N. The polymeric matrix can include poly(vinylidine)fluoride-trifluoroethylene-chlorofluoroeethylene) (PVDF-TrFE-CFE) terpolymer. In a preferred embodiment, the polymeric matrix is PVDF-TrFE-CFE. The amount of lead-free piezoelectric material can be greater than 10 vol. % or 30 vol. % to 70 vol. %, preferably 40 vol. % to about 60 vol. % based on the total volume of the composite. Lead-free piezoelectric materials can include barium titanate (BaTiO₃), potassium sodium niobate (KNaNb)O₃ (KNN), potassium lithium sodium niobate (KLi)(NaNb)O₃ (KLNN), hydroxyapatite, apatite, lithium sulfate monohydrate, sodium bismuth titanate, quartz, an organic material (preferably, tartaric acid or poly(vinylidene difluoride) fibers), or combinations thereof. In a certain embodiment, the polymeric matrix is PVDF-TrFE-CFE and the piezoelectric material is BaTiO₃, KLNN, or KNN. When subjected to temperatures greater than 90° C., preferably greater than 90° C. or 90° C. to 130° C., the lead-free piezoelectric composites of the present invention can retain their d₃₃ value. The lead-free piezoelectric composites of the present invention can be oriented at an electric polarization voltage lower when compared with the same polymer matrix in the absence of the lead-free piezoelectric filler when subjected to the an electric field. In some embodiments, the lead-free piezoelectric composites of the present invention can be flexible sheets or films. Such sheets or films can have a thickness of 50 to 200 microns.

The lead-free composites of the present invention can be included in an article of manufacture. Articles of manufacture can include component of a touch panel, a human machine interface, an integrated keyboard, or a wearable device.

In another aspect of the present invention, a piezoelectric device can include the lead-free piezoelectric polymeric composites of the present invention. The device can be a piezoelectric sensor, a piezoelectric transducer, or a piezoelectric actuator. In a preferred instance, the device is mechanically flexible.

In yet another aspect of the present invention, methods of forming the lead-free piezoelectric composites of the present invention are described. A method can include (a) adding lead-free piezoelectric particles to a solution that includes a solubilized polymeric material having a dielectric constant of greater than 10 and a solvent to form a dispersion or suspension where the lead-free piezoelectric particles are dispersed or suspended in the solution, (b) forming a polymeric matrix having the lead-free piezoelectric particles dispersed or suspended therein, and (c) subjecting the polymeric matrix having the lead-free piezoelectric particles dispersed therein to an electric polarization treatment to form the lead-free piezoelectric composite of the present invention. The polymeric material to solvent ratio can be 1:5 to 1:10. Forming the polymeric matrix can include (i) casting the dispersion on a substrate, (ii) drying the polymeric matrix at 25° C. to 80° C. to form the polymeric matrix, and (iii) annealing the dried polymeric matrix at a temperature of 80 to 150° C. for 1 to 50 hours, preferably 110° C. for 5 to 25 hours. Inducing the electric polarization can include applying a poling field using corona discharge. In a particular aspect, the polymeric material can be PVDF-TrFE-CFE, the lead-free piezoelectric material can be KLNN, KNN, BaTiO₃, or a combination thereof, and the solvent can be tetrahydrofuran, methyl ethyl ketone, dimethyl sulfoxide, ethyl acetate, amyl acetate, dimethyl formamide, dimethyl acetamide, or any combination thereof.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to other aspects of the invention. It is contemplated that any embodiment discussed herein can be implemented with respect to any method or composition of the invention, and vice versa. Furthermore, compositions and kits of the invention can be used to achieve methods of the invention.

The following includes definitions of various terms and phrases used throughout this specification.

The terms “about” or “approximately” are defined as being close to as understood by one of ordinary skill in the art. In one non-limiting embodiment, the terms are defined to be within 10%, preferably within 5%, more preferably within 1%, and most preferably within 0.5%.

The terms “wt. %”, “vol. %”, or “mol. %” refers to a weight percentage of a component, a volume percentage of a component, or molar percentage of a component, respectively, based on the total weight, the total volume of material, or total moles, that includes the component. In a non-limiting example, 10 grams of component in 100 grams of the material is 10 wt. % of component.

The term “substantially” and its variations are defined to include ranges within 10%, within 5%, within 1%, or within 0.5%.

The terms “inhibiting” or “reducing” or “preventing” or “avoiding” or any variation of these terms, when used in the claims and/or the specification includes any measurable decrease or complete inhibition to achieve a desired result.

The term “effective,” as that term is used in the specification and/or claims, means adequate to accomplish a desired, expected, or intended result.

The use of the words “a” or “an” when used in conjunction with any of the terms “comprising,” “including,” “containing,” or “having” in the claims, or the specification, may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The piezoelectric composite of the present invention can “comprise,” “consist essentially of,” or “consist of” particular ingredients, components, compositions, etc. disclosed throughout the specification. With respect to the transitional phrase “consisting essentially of,” in one non-limiting aspect, a basic and novel characteristic of the piezoelectric composite, of the present invention is their high flexibility and high piezoelectric properties compared to PVDF.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description. In further embodiments, features from specific embodiments may be combined with features from other embodiments. For example, features from one embodiment may be combined with features from any of the other embodiments. In further embodiments, additional features may be added to the specific embodiments described herein.

### BRIEF DESCRIPTION OF THE DRAWINGS

Advantages of the present invention may become apparent to those skilled in the art with the benefit of the following detailed description and upon reference to the accompanying drawings.

FIG. 1 represents variations of piezoelectric coefficient d₃₃(pC/N) of comparative piezoelectric composites having increasing volume fraction of PZT volume fraction and lead-free piezoelectric composites of the present invention having increasing volume fraction of KLNN.

FIG. 2 represents variations of dielectric constant comparative piezoelectric composites having increasing volume fraction of PZT volume fraction and lead-free piezoelectric composites of the present invention having increasing volume fraction of KLNN.

While the invention is susceptible to various modifications and alternative forms, specific embodiments thereof are shown by way of example in the drawings. The drawings may not be to scale.

### DETAILED DESCRIPTION OF THE INVENTION

Flexible lead-free piezoelectric composites of the present invention with high piezoelectric charge constant values can provide a solution to at least some of the problems associated with PVDF-based and ceramic-based piezoelectric composites. The solution is premised on using a polymeric matrix (e.g., PVDF-TrFE-CFE) having a dielectric constant greater than 30 at 20° C. having at least 10 vol. % of lead-free piezoelectric material, based on the total volume of the composite, dispersed throughout the polymeric matrix. Such a lead-free piezoelectric composites can have a piezoelectric coefficient d₃₃ of greater than 20 pC/N and be flexible (e.g., have an elastic modulus of less than 1 GPa). By combining polymer-based materials with ceramic-based materials, the composites of the present invention can produce lead-free piezoelectric materials that have the desired piezoelectric and mechanical properties, which can be especially advantageous for flexible sensor-based applications and/or wearable devices and articles of manufacture.

These and other non-limiting aspects of the present invention are discussed in further detail in the following sections.

### A. Materials

1. Piezoelectric Materials

The piezoelectric material can be any lead-free ceramic or single crystal material. Non-limiting examples of piezoelectric materials include inorganic compounds of the perovskite family. Non-limiting examples of piezoelectric ceramics with the perovskite structure include barium titanate BaTiO₃, potassium sodium niobate (KNaNb)O₃ (KNN), potassium lithium sodium niobate (KLi)(NaNb)O₃ (KLNN), hydroxyapatite, apatite, lithium sulfate monohydrate, sodium bismuth titanate, quartz, an organic material (preferably, tartaric acid or poly(vinylidene fluoride) fibers), or combinations thereof. The lead-free piezoelectric particles can have a particle size of 200 nm to 3000 nm, or at least greater than any one of, equal to any one of, or between any two of 200 nm, 225 nm, 250 nm, 275 nm, 300 nm, 325 nm, 350 nm, 375 nm, 400 nm, 425 nm, 450 nm, 475 nm, 500 nm, 525 nm, 550 nm, 575 nm, 600 nm, 625 nm, 650 nm, 675 nm, 700 nm, 725 nm, 750 nm, 775 nm, 800 nm, 825 nm, 850 nm, 875 nm, 900 nm, 925 nm, 950 nm, 975 nm, 1000 nm, 1500 nm, 2000 nm, 2500 nm, and 3000 nm. By way of example, BaTiO₃ can have a particle size of 200 to 500 nm, or 250 to 400 nm, or 300 to 350 nm. In another example KNLN can have a particle size of 1000 to 3000 nm (1 to 3 microns), or 1500 to 2500 nm. Table 1 lists properties of some lead-free piezoelectric materials.

TABLE 1

| | T_{c} | | d₃₃ |
|---|---|---|---|
| Material | (° C.) | εᵣ | (pC/N) |
| BT | 120 | 1800 | 190 |
| BNT | 200 | 700 | 120 |
| KLNN | 340-475 | 220 | 200-490 |

2. Polymers

The piezoelectric composites of the present invention can include a polymeric matrix having a dielectric constant greater than 30 at 20° C. The polymeric matrix can include a thermoset polymer, copolymer and/or monomer, a thermoplastic polymer, copolymer and/or monomer or a thermoset/thermoplastic polymer or copolymer blend.

Non-limiting examples of thermoset polymeric matrices include those comprising an epoxy resin, an unsaturated polyester resin, a polyurethane, bakelite, duroplast, urea-formaldehyde, diallyl-phthalate, an epoxy vinylester, a polyimide, a cyanate ester of polycyanurate, dicyclopentadiene, a phenolic, a benzoxazine, co-polymers thereof, or blends thereof. In a particularly preferred embodiment, the thermoset polymeric matrix is an epoxy resin. The epoxy resin can include diglycidyl ether bisphenol-A and polyoxypropylene diamine. In another instance, the polymeric matrix can be a thermoplastic polymeric matrix. Non-limiting examples of thermoplastic polymeric matrices include those that include polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), poly(phenylene oxide) (PPO), polypropylene (PP), polyethylene (PE), polyvinyl chloride (PVC), polystyrene (PS), polymethyl methacrylate (PMMA), polyethyleneimine or polyetherimide (PEI) and their derivatives, thermoplastic elastomer (TPE), terephthalic acid (TPA) elastomers, poly(cyclohexanedimethylene terephthalate) (PCT), polyethylene naphthalate (PEN), polyamide (PA), polysulfone sulfonate (PSS), sulfonates of polysulfones, polyether ether ketone (PEEK), acrylonitrile butyldiene styrene (ABS), polyether ketone ketone (PEKK), polyphenylene sulfide (PPS), co-polymers thereof, or blends thereof.

Non-limiting examples of thermoplastic polymers that can be used in the context of the present invention include poly(vinylidine)fluoride-trifluoroethylene-chlorofluoroeethylene) (PVDF-TrFE-CFE) terpolymer, odd-numbered nylon, cyano-polymer, polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), poly(phenylene oxide) (PPO), polypropylene (PP), polyethylene (PE), polyvinyl chloride (PVC), polystyrene (PS), polymethyl methacrylate (PMMA), polyethyleneimine or polyetherimide (PEI) and their derivatives, thermoplastic elastomer (TPE), terephthalic acid (TPA) elastomers, poly(cyclohexanedimethylene terephthalate) (PCT), polyethylene naphthalate (PEN), polyamide (PA), polysulfone sulfonate (PSS), sulfonates of polysulfones, polyether ether ketone (PEEK), polyether ketone ketone (PEKK), acrylonitrile butyldiene styrene (ABS), polyphenylene sulfide (PPS), co-polymers thereof, or blends thereof. In a preferred instance, a PVDF-TRFE-CFE is used, which has a dielectric constant of about 50.

Additives can be included with the polymers to form polymeric matrices that include the additives. Non-limiting examples of additives include coupling agents, antioxidants, heat stabilizers, flow modifiers, colorants, etc., or any combinations thereof.

### B. Method of Producing Piezoelectric Composites

The piezoelectric composite of the present invention can be made using solution casting or forming methodology. A solution of a polymer described in the Materials section can be obtained. The solution can include a solvent and polymer described in the Materials section, preferably PVDF-TRFE-CFE. Non-limiting examples of solvents include tetrahydrofuran (THF), methyl ethyl ketone (MEK), dimethylsulfoxide (DMSO), N-methyl-2-pyrrolidone (NMP), or combinations thereof. The polymer to solvent ratio can range between 1:5 to 1:10, 1:6 to 1:9, or about 1:8. In some embodiments, the solution includes at least any one of, equal to any one of, or between any two of 10 wt. %, 20 wt. %, 30 wt. %, 40 wt. %, or 50 wt. %, or about 12.5 wt. % of PVDF-TRFE-CFE. In some embodiments, no compatibility improvers are used to make the lead-free polymeric composites of the present invention.

The piezoelectric material can be dispersed or suspended in the polymer solution. The piezoelectric material can be a plurality (e.g., 2 or more, suitably 5 or more, 10 or more, 50 or more, 100 or more, 500 or more, 1000 or more, etc.) of lead-free piezoelectric particles. The lead-free piezoelectric particles can be dispersed in the solution via any suitable method, including mixing, stirring, folding or otherwise integrating the lead-free piezoelectric particles in the matrix so as to generate a uniform dispersion or suspension of the particles in the matrix. In some embodiments, the solution is added to the piezoelectric material.

The dispersion or suspension can be subjected to conditions suitable to form the piezoelectric composites of the present invention. The terms dispersion and suspension can be used interchangeably throughout this specification. In one instance, the dispersion includes PVDF-TRFE-CFE and barium titanate. In another instance, the dispersion includes PVDF-TRFE-CFE and KLNN. In some embodiments, the dispersion can be shaped or cast. Shaped or shaping or casting can include a mechanical or physical process to change the dispersion to a desired form. Shaped or shaping or casting can also include placing a dispersion into a desired container or receptacle, thereby providing it with a maintained shape or form. It should be noted that the shaped form is not necessarily the final form, as additional processing (e.g., machining, forming, etc.) can be completed on the final, cured composite. The act of shaping or casting the dispersion for use in the methods described herein is primarily to give some initial structure to the dispersion prior to further processing. A rigid or specific shape can be obtained but is not required.

Casting can include pouring the dispersion on a casting surface. Non-limiting examples of casting include air casting (e.g., the dispersion passes under a series of air flow ducts that control the evaporation of the solvents in a particular set period of time such as 24 to 48 hours), solvent, or emersion casting, (e.g., the dispersion is spread onto a moving belt and run through a bath or liquid in which the liquid within the bath exchanges with the solvent). The spreading of the dispersion on the casting surface can be done with a doctor blade, rolling spreader bar or any of several configurations of flat sheeting extrusion dies.

During casting or shaping, the solvent can be removed thereby leaving the dispersion on the substrate or in the mold. Heat can be applied to assist in the removal of the solvent. By way of example, the shaped material can be heated at a temperature of at least any one of, equal to any one of, or between any two of 25° C., 30° C., 35° C., 40° C., 45° C., 50° C., 55° C., 60° C., 65° C., 70° C., 75° C., and 80° C. The resulting shaped polymeric composite material can be annealed at a temperature of at least any one of, equal to any one of, or between any two of 80° C., 85° C., 90° C., 95° C., 100° C., 105° C., 110° C., 115° C., 120° C., 125° C., 130° C., 135° C., 140° C., 145° C., and 150° C. for a desired amount of time (e.g., 5, 10, 15, 20, 25 30, 35, 40, 45, 50 hours or any range or value there between). The shaped material can be a film, a sheet or the like.

After annealing the shaped polymeric composite material can be subjected conditions to induce electric polarization in the lead-free piezoelectric material (e.g., plurality of particles) in the polymeric composited material. During electric polarization, the piezoelectric particles can be connected to one another in a linear or semi-linear manner (e.g., chains of particles). Columns of piezoelectric particles are suitably formed by the stacking or aligning of more than one chain. In a non-limiting example, the shaped polymeric composite material can be poled. By way of example, the polymeric composite material can be poled with a selected electric field at room temperature (e.g., after cooling of the composite), or at a selected electric field at a selected temperature, at least one of the selected electric field and the selected temperature being chosen in accordance with a desired dipole orientation, a desired polarization strength, or property of the article of manufacture.

The temperature for performing poling can be in accordance with a desired dipole orientation and/or a desired polarization strength, or in accordance with a desired stress state of a finished actuator. For example, the poling of polymeric composite materican can be performed at a selected cooling temperature range, through a selected heating temperature, or through a selected heating temperature heating and cooling temperature range. In some instance, the poling may occur over a “range” (e.g., selected range) of temperatures rather than at a specific constant temperature. In some embodiments, poling can be performed at a temperature of at least, equal to, or between any two of 80° C., 85° C., 90° C., 95° C., 100° C., 105° C., 110° C., 115° C., and 120° C. The applied voltage level parameter for the poling can be selected in various ways. For example, the applied voltage level parameter can be selected as constant, or changing (e.g., ramped) over a period of time. In some embodiments, poling is performed using corona discharge using an electrode gap of 0.5 to 1.5 cm, or about 1 cm for a desired amount of time (e.g., about 1 hour) at 6 to 15 kV/m or 10 to 13 kV/m or any range or value therebetween.

### C. Piezoelectric Composite

The piezoelectric composite can include a polymer and a lead-free piezoelectric material. The piezoelectric composite can include at least any one of, equal to any one of, or between any two of 10, 20, 30, 40, 45, 50, 55, 60, 65, 70, 75, 80, 85, 90, 95, and 99 wt. % of the polymer that forms the polymer matrix. The amount of lead-free piezoelectric additive present in the polymer matrix can be at least, equal to, or between any two of 10, 15, 20, 25, 30, 35, 40, 45, 50, 55, 60, 65, and 70 vol. %. In some embodiments, the piezoelectric composite includes PVDF-TRFE-CFE and 20 vol. % to 60 vol. %, or 40 vol. % to 60 vol. % barium titanate particles. In some embodiments, the piezoelectric composite includes PVDF-TRFE-CFE and 20 vol. % to 60 vol. %, or 40 vol. % to 60 vol. % KLNN particles. In some embodiments, the piezoelectric composite includes, consists of, or consists essentially of PVDF-TRFE-CFE and 20 vol. % to 60 vol. % barium titanate particles having an average particle size of 200 to 500 nm. In some embodiments, the piezoelectric composite includes, consists of, or consists essentially of PVDF-TRFE-CFE and 20 vol. % to 60 vol. % KLNN particles.

In some embodiments, the piezoelectric composite can have any shape or form. In some embodiments, the piezoelectric composite is a film or sheet. In some embodiments, the film or sheet has a thickness dimension of 50 to 200 microns, or at least, equal to, or between any two of 50, 60, 70, 80, 90, 100, 110, 120, 130, 140, 150, 160, 170, 180, 190, and 200 microns.

Properties of the piezoelectric composite include electrical and mechanical properties. Non-limiting examples of electrical properties can include piezoelectric constant, dielectric constant, and the like. The d₃₃ of the piezoelectric composite be greater than any one of, equal to any one of, or between any two of 20 pC/N, 25 pC/N, 30 pC/N, 35 pC/N, 40 pC/N, 45 pC/N, 50 pC/N, 55 pC/N, 56 pC/N, 57 pC/N, 58 pC/N, 59 pC/N, and 60 pC/N. The piezoelectric composite can have a dielectric constant that is between 30 to 210, or at least one of, equal to any one of, or between any two of 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, and 210. The lead-free piezoelectric composite can have a storage modulus can range from 100 to 325 MPa, or at least, equal to, or between any two of 100, 125, 150, 175, 200, 225, 250, 275, 300, and 325 MPa. Storage modulus can be measured according to ISO 6721 at room temperature and a 1 Hz strain of 0.2%. The lead-free piezoelectric composite can have an elongation break of 100 to 500% under uniaxial loading at room temperature (e.g., 25 to 35° C.). Elongation break can be measured using standard dynamic mechanical analyzer such as a RDA III analyser (TA Instruments, U.S.A.). The lead-free piezoelectric composite can have an elastic modulus of less than 1 GPa, or from 0.1 to 0.99 GPa, or less than any one of, equal to any one of, or between any two of 0.1, 0.25, 0.5, 0.75, 0.8, 0.9, 0.99 GPa. Elastic modulus can be measured using a universal tensile testing machine. Notably, composites when tested up to 110° C. and they retained their piezoelectric properties without depoling.

### D. Devices and Articles of Manufacture

The piezoelectric composites of the present invention can be incorporated into a device. In a preferred instance, the device is flexible. In some particular, instances, the piezoelectric composites of the present invention can be used in articles of manufacture that have curved surfaces, flexible surfaces, deformable surfaces, etc. Non-limiting examples of such articles of manufacture include a piezoelectric sensor, a piezoelectric transducer, a piezoelectric actuator. These components can be used in tactile sensitive devices, electronic devices (e.g., smart phones, tablets, computers, etc.), virtual reality devices, augmented reality devices, fixtures that require flexibility such as adjustable mounted wireless headsets and/or ear buds, communication helmets with curvatures, medical batches, flexible identification cards, flexible sporting goods, packaging materials, medical devices, and/or applications where the presence of a bendable material simplifies final product design, engineering, and/or mass production.

### EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### Example 1

### Preparation of Piezoelectric Material of the Present Invention

PVDF-TrFE-CFE (RT™-CFE Standard Composition Powder) was obtained from Piezotech®, Arkema Group (France). BaTiO₃ (BT) was obtained from Inframat Corporation (U.S.A.). KLNN was prepared following the procedure of WO 2016157092 to Bella et al. PVDF-TrFE-CFE was dissolved in tetrahydrofuran (THF) by magnetic stirring with a polymer to solvent ratio of 1:8 at 25° C. for 1 hour in an oil bath at a speed of 50 rpm. After complete dissolution of the polymer, different volume fractions of BT or KLNN were added to the solution and stirred at 300 rpm for 30 minutes to completely homogenize the BT or KLNN powder inside the PVDF-TrFE-CFE solution. After homogenization, the mixture was casted as onto a glass plate, or a glass plate wrapped with an aluminium foil. The casted films were dried at room temperature and subsequently annealed at 110° C. for 2-5 hours under atmospheric conditions. The samples were poled at 110° C. for 0.5 hour under 10 KV/mm. Table 2 lists the properties of PZT and the lead-free piezoelectric materials. Table 3 lists the compositions of the lead-free piezoelectric composites of the present invention.

TABLE 2

| | T_{c} | | d₃₃ |
|---|---|---|---|
| Material | (° C.) | εᵣ | (pC/N) |
| PZT | 165-360 | 1000-3800 | 250-700 |
| BT | 120 | 1800 | 190 |
| KLNN | 340-475 | 220 | 200-490 |

TABLE 3

| | | Lead free | | |
|---|---|---|---|---|
| Sample | | piezoceramic | Loading | d33 |
| id | Polymer | filler | (vol %) | (pC/N) |
| 1* | PVDF-TrFE-CFE | BT | 40 | 49.6 |
| 2* | PVDF-TrFE-CFE | BT | 60 | 51.6 |
| 3** | PVDF-TrFE-CFE | BT | 50 | 40.0 |
| 4** | PVDF | BT | 50 | 19.0 |
| 5* | PVDF-TrFE-CFE | KLNN | 40 | 47.2 |
| 6** | PVDF-TrFE-CFE | KLNN | 50 | 43 |

*Free standing piezocomposite film
**Aluminium foil supported film
***Piezocomposite films prepared using corona poling technique

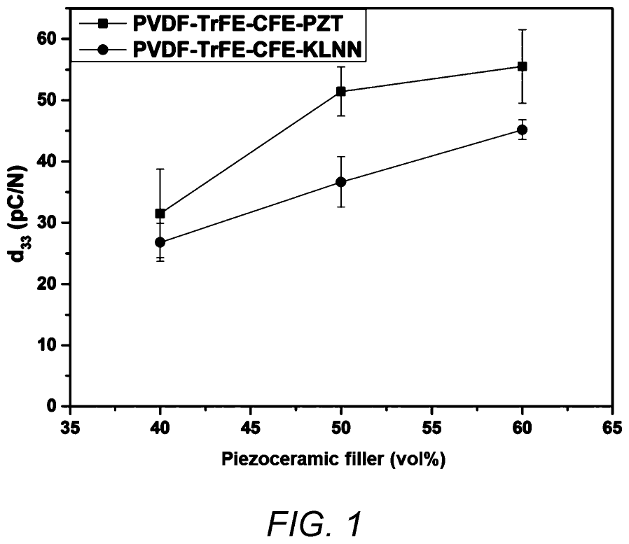

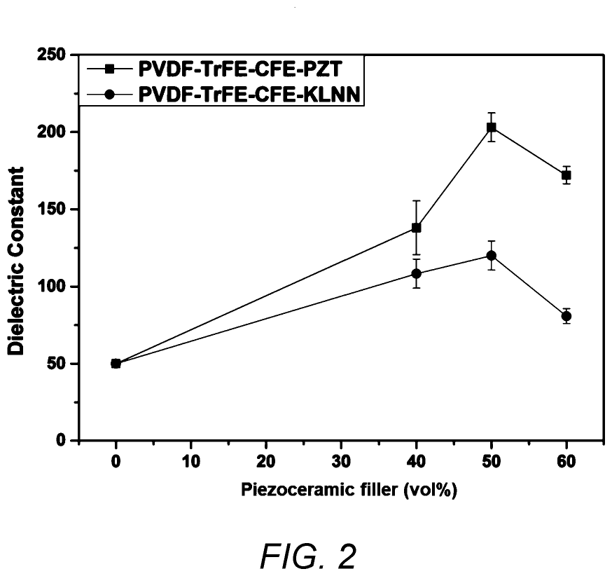

FIG. 1 represents variation of d₃₃ with increasing PZT volume fraction (comparative sample) and KLNN. FIG. 2 represents variation of dielectric constant with increasing PZT volume fraction (comparative sample) and KLNN. While the KLNN samples showed lower d₃₃, the results are acceptable for a lead free as it has a high d₃₃, a low dielectric constant and a high curie temperatures. Both PZT and lead free piezoceramic described in the invention, barium titanate and KLNN are perovskites. The properties of the piezoceramics are summarized in the Table 2.

In the context of the present invention, at least twenty embodiments are now described. Embodiment 1 is a lead-free piezoelectric composite. The composite contains a polymeric matrix having a dielectric constant greater than 30 at 20° C.; and greater than 10 vol. % of a lead-free piezoelectric material based on the total volume of the composite dispersed throughout the polymeric matrix. The lead-free piezoelectric composite has an elastic modulus of less than 1 GPa and a piezoelectric coefficient d₃₃ of greater than 20 pC/N. Embodiment 2 is the lead-free piezoelectric composite of embodiment 1, wherein the polymeric matrix contains poly(vinylidine)fluoride-trifluoroethylene-chlorofluoroeethylene) (PVDF-TrFE-CFE) terpolymer. Embodiment 3 is the lead-free piezoelectric composite of any one of embodiments 1 or 2, wherein the polymeric matrix is PVDF-TrFE-CFE. Embodiment 4 is the lead-free piezoelectric composite of any one of embodiments 1 to 3, wherein the amount of lead-free piezoelectric material is 30 vol. % to 70 vol. %, preferably 40 vol. % to about 60 vol. % based on the total volume of the composite. Embodiment 5 is the lead-free piezoelectric composite of any one of embodiments 1 to 4, wherein the piezoelectric material contains barium titanate (BaTiO₃), potassium sodium niobate (KNaNb)O₃ (KNN), potassium lithium sodium niobate (KLi)(NaNb)O₃ (KLNN), hydroxyapatite, apatite, lithium sulfate monohydrate, sodium bismuth titanate, quartz, an organic material preferably, tartaric acid or poly(vinylidene difluoride) fibers, or combinations thereof. Embodiment 6 is the lead-free piezoelectric composite of any one of embodiments 1 to 5, wherein the polymeric matrix is PVDF-TrFE-CFE and the piezoelectric material is BaTiO₃. Embodiment 7 is the lead-free piezoelectric composite of any one of embodiments 1 to 6, wherein the polymeric matrix is PVDF-TrFE-CFE and the piezoelectric material is KLNN. Embodiment 8 is the lead-free piezoelectric composite of any one of embodiments 1 to 7, wherein the polymeric matrix is PVDF-TrFE-CFE and the piezoelectric material is KNN. Embodiment 9 is the lead-free piezoelectric composite of any one of embodiments 1 to 8, wherein the composite retains its d₃₃ value at temperatures of greater than 90° C. Embodiment 10 is the lead-free piezoelectric composite of any one of embodiments 1 to 9, wherein the composite is oriented at an electric polarization voltage lower when compared with the same polymer matrix in the absence of the lead-free piezoelectric filler when subjected to the an electric field. Embodiment 11 is the lead-free piezoelectric composite of any one of embodiments 1 to 10, wherein the composite is a flexible sheet or film. Embodiment 12 is the lead-free piezoelectric polymeric composite of embodiment 11, wherein the film or sheet has a thickness of 50 to 200 microns. Embodiment 13 is the lead-free piezoelectric composite of any one of embodiments 1-12, further comprised in an article of manufacture. Embodiment 14 is the lead-free piezoelectric composite of embodiment 13, wherein the article of manufacture is a component of a touch panel, a human machine interface, an integrated keyboard, or a wearable device.

Embodiment 15 is a piezoelectric device including any one of the lead-free piezoelectric polymeric composites of embodiments 1-12, wherein the device is preferably a piezoelectric sensor, a piezoelectric transducer, or a piezoelectric actuator, and wherein the device is preferably mechanically flexible. Embodiment 16 is a method of forming the lead-free piezoelectric composite of any one of embodiments 1-12, the method including: (a) adding lead-free piezoelectric particles to a solution containing a solubilized polymeric material having a dielectric constant of greater than 10 and a solvent to form a dispersion or suspension where the lead-free piezoelectric particles are dispersed or suspended in the solution; (b) forming a polymeric matrix having the lead-free piezoelectric particles dispersed therein; and (c) subjecting the polymeric matrix having the lead-free piezoelectric particles dispersed therein to an electric polarization treatment to form the lead-free piezoelectric composite of any one of embodiments 1-12. Embodiment 17 as the method of embodiment 16, wherein forming the polymeric matrix contains: (i) casting the dispersion on a substrate; (ii) drying the polymeric matrix at 25° C. to 80° C. to form the polymeric matrix; and (iii) annealing the dried polymeric matrix at a temperature of 80 to 150° C. for 1 to 50 hours, preferably 110° C. for 5 to 25 hours. Embodiment 18 is the method of any one of embodiments 16 to 17, wherein inducing the electric polarization contains applying a poling field using corona discharge. Embodiment 19 is the method of any one of embodiments 16 to 18, wherein the polymeric material is poly(vinylidene fluoride-trifluoroethylene-chlorofluoroethylene), the lead-free piezoelectric material is KLNN, KNN, BaTiO₃, or a combination thereof, and the solvent is tetrahydrofuran, methyl ethyl ketone, dimethyl sulfoxide, ethyl acetate, amyl acetate, dimethyl formamide, dimethyl acetamide, or any combination thereof. Embodiment 20 is the method of any one of embodiments 16 to 19, wherein the polymeric material to solvent ratio is 1:5 to 1:10.

Although embodiments of the present application and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the above disclosure, processes, machines, manufacture, compositions of matter, means, methods, or steps, presently existing or later to be developed that perform substantially the same function or achieve substantially the same result as the corresponding embodiments described herein can be utilized. Accordingly, the appended claims are intended to include within their scope such processes, machines, manufacture, compositions of matter, means, methods, or steps.

1. A lead-free piezoelectric composite comprising:
a polymeric matrix having a dielectric constant greater than 30 at 20° C.; and
greater than 10 vol. % of a lead-free piezoelectric material based on the total volume of the composite dispersed throughout the polymeric matrix,
wherein the lead-free piezoelectric composite has an elastic modulus of less than 1 GPa and a piezoelectric coefficient d₃₃ of greater than 20 pC/N.

2. The lead-free piezoelectric composite of claim 1, wherein the polymeric matrix comprises poly(vinylidine)fluoride-trifluoroethylene-chlorofluoroeethylene) (PVDF-TrFE-CFE) terpolymer.

3. The lead-free piezoelectric composite of any one of claim 2, wherein the polymeric matrix is PVDF-TrFE-CFE.

4. The lead-free piezoelectric composite of claim 1, wherein the amount of lead-free piezoelectric material is 30 vol. % to 70 vol. % based on the total volume of the composite.

5. The lead-free piezoelectric composite of claim 1, wherein the piezoelectric material comprises a member selected from the group consisting of barium titanate (BaTiO₃), potassium sodium niobate (KNaNb)O₃ (KNN), potassium lithium sodium niobate (KLi)(NaNb)O₃ (KLNN), hydroxyapatite, apatite, lithium sulfate monohydrate, sodium bismuth titanate, quartz, an organic material preferably, tartaric acid and poly(vinylidene difluoride) fibers, or combinations thereof.

6. The lead-free piezoelectric composite of claim 1, wherein the polymeric matrix is PVDF-TrFE-CFE and the piezoelectric material is BaTiO₃.

7. The lead-free piezoelectric composite of claim 1, wherein the polymeric matrix is PVDF-TrFE-CFE and the piezoelectric material is KLNN.

8. The lead-free piezoelectric composite of claim 1, wherein the polymeric matrix is PVDF-TrFE-CFE and the piezoelectric material is KNN.

9. The lead-free piezoelectric composite of claim 1, wherein the composite retains its d₃₃ value at temperatures of greater than 90° C.

10. The lead-free piezoelectric composite of claim 1, wherein the composite is oriented at an electric polarization voltage lower when compared with the same polymer matrix in the absence of the lead-free piezoelectric filler when subjected to the an electric field.

11. The lead-free piezoelectric composite of claim 1, wherein the composite is a flexible sheet or film.

12. The lead-free piezoelectric polymeric composite of claim 11, wherein the film or sheet has a thickness of 50 to 200 microns.

13. The lead-free piezoelectric composite of claim 1, further comprised in an article of manufacture.

14. The lead-free piezoelectric composite of claim 13, wherein the article of manufacture is a component of a touch panel, a human machine interface, an integrated keyboard, or a wearable device.

15. A piezoelectric device comprising the lead-free piezoelectric polymeric composite of claim 1, wherein the device is a piezoelectric sensor, a piezoelectric transducer, or a piezoelectric actuator, and wherein the device is mechanically flexible.

16. A method of forming the lead-free piezoelectric composite of claim 1, the method comprising:
(a) adding lead-free piezoelectric particles to a solution comprising a solubilized polymeric material having a dielectric constant of greater than 10 and a solvent to form a dispersion or suspension where the lead-free piezoelectric particles are dispersed or suspended in the solution;
(b) forming a polymeric matrix having the lead-free piezoelectric particles dispersed therein; and
(c) subjecting the polymeric matrix having the lead-free piezoelectric particles dispersed therein to an electric polarization treatment to form the lead-free piezoelectric composite.

17. The method of claim 16, wherein forming the polymeric matrix comprises:
(i) casting the dispersion on a substrate;
(ii) drying the polymeric matrix at 25° C. to 80° C. to form the polymeric matrix; and
(iii) annealing the dried polymeric matrix at a temperature of 80 to 150° C. for 1 to 50 hours.

18. The method of claim 16, wherein inducing the electric polarization comprises applying a poling field using corona discharge.

19. The method of claim 16, wherein the polymeric material is poly(vinylidene fluoride-trifluoroethylene-chlorofluoroethylene), the lead-free piezoelectric material is selected from the group consisting of KLNN, KNN and BaTiO₃, or a combination thereof, and the solvent is selected from the group consisting of tetrahydrofuran, methyl ethyl ketone, dimethyl sulfoxide, ethyl acetate, amyl acetate, dimethyl formamide and dimethyl acetamide, or any combination thereof.

20. The method of claim 16, wherein the polymeric material to solvent ratio is 1:5 to 1:10.
